(19) United States
(12) Patent Application Publication
(10) Pub. No.: US 2007/0082425 A1
(43) Pub. Date: Apr. 12, 2007

(54) Using a center pole illumination scheme to improve symmetry for contact hole lithography

(75) Inventors: Scott William Jessen, Allen, TX (US); Robert Soper, Plano, TX (US); Mark Terry, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/246,246

(22) Filed: Oct. 11, 2005

(51) Int. Cl. H01L 21/00

(52) U.S. Cl. 438/97

(57) ABSTRACT

In accordance with an embodiment the invention, there is a device manufacturing method. The method can comprise providing a substrate comprising a radiation-sensitive material disposed thereon and directing a beam of radiation through an aperture such that the radiation produces at least two illumination poles. The method can also comprise exposing the substrate to the at least two illumination poles using off-axis illumination and varying a size of a first illumination pole of the at least two illumination poles with respect to a second illumination pole of the at least two illumination poles.

### DESCRIPTION OF THE INVENTION

1. Field of the Invention

The subject matter of this application relates to photolithography systems. More particularly, the subject matter of this application relates to methods and devices for forming symmetric contact holes on semiconductor devices.

2. Background of the Invention

Lithographic projection apparatus (tools) can be used, for example, in the manufacture of integrated circuits (ICs). When using the various tools, a mask can be used that contains a circuit pattern corresponding to an individual layer of the IC, and this pattern can be imaged onto a target portion (e.g., comprising one or more dies) on a substrate, such as a silicon or other wafer comprising a semiconductor, that has been coated with a layer of radiation-sensitive material, such as a resist. In general, a single wafer may contain a network of adjacent target portions that can be successively irradiated using a projection system of the tool, one at a time. In one type of lithographic projection apparatus, each target portion is irradiated by exposing the entire mask design onto the target portion in one shot. In another apparatus, which is commonly referred to as a step-and-scan apparatus, each target portion is irradiated by progressively scanning the mask design under the projection beam in a given reference direction (the “scanning” direction) while synchronously scanning the substrate table parallel or anti-parallel to the scanning direction. Because the projection system typically has a magnification factor M, which is generally less than 1, the speed V at which the substrate table is scanned will be a factor M times that at which the mask table is scanned.

In a manufacturing process using a lithographic projection apparatus, a mask design can be imaged onto a substrate that is at least partially covered by a layer of resist. Prior to this imaging step, the substrate may undergo various procedures, such as, priming, resist coating, and a soft bake. After exposure, the substrate can be subjected to other procedures, such as a post-exposure bake (PEB), development, a hard bake, and a measurement/inspection of the image structures. This array of procedures can be used as a basis to pattern an individual layer of a device, such as an IC. Such a patterned layer may then undergo various processes, such as etching, ion-implantation, doping, metallization, oxidation, chemical mechanical polishing (CMP), etc., all intended to complete an individual layer. If several layers are required, then part or all of the procedure, or a variant thereof, may need to be repeated for each new layer. Eventually, an array of structures, and ultimately devices can be present on the substrate. These devices can then be separated from one another by a technique such as dicing or sawing. Thereafter, the individual devices can be mounted on a carrier, connected to pins, etc.

The lithographic tool may be of a type having two or more substrate tables (and/or two or more mask tables). In such “multiple stage” devices, the additional tables may be used in parallel, or preparatory steps may be carried out on one or more tables while one or more other tables are being used for exposure.

The photolithography masks referred to above comprise geometric features corresponding to the circuit components to be integrated onto a substrate. The layout used to create such masks are typically generated using computer-aided design (CAD) programs, sometimes called electronic design automation (EDA). Most CAD programs follow a set a predetermined design rules in order to create functional masks. These rules are set by processing and design limitations. For example, design rules attempt to define the space tolerance between circuit devices, such as contact holes, gates, capacitors, etc., or interconnect lines, so as to ensure that the circuit devices or lines do not interact with one another in an undesirable way.

One of the goals in IC fabrication is to faithfully reproduce the original circuit design from the layout on the wafer using the mask. Another goal is to use as much of the wafer real estate as possible. As the size of an IC is reduced and its density increases, however, the critical dimension (CD) of its corresponding mask design approaches the resolution limit of the optical exposure tool. The resolution for an exposure tool can be defined as the minimum feature sizes that the exposure tool can repeatedly expose on the wafer. The resolution value of present exposure tools often constrains the CD for many advanced IC designs.

Furthermore, the constant improvements in micro-processor speed, memory packing density, and low power consumption for micro-electronic components can be directly related to the ability of lithography techniques to transfer and form structures onto the various layers of a semiconductor device. In order to keep pace with Moore's law and develop sub-wavelength resolution, it has become necessary to use a variety of resolution enhancement techniques (RET).

Historically, the Rayleigh criteria for resolution (R) and depth of focus (DOF) have been used to evaluate the performance of a given technology. The Rayleigh criteria has been defined by:
R=k₁λ/NA (1)
DOF=±k₂λ/NA² (2)

where k₁ and k₂ are process dependent factors, λ is wavelength, and NA is numerical aperture. Depth of focus is one of the factors determining the resolution of the lithographic apparatus and is defined as the distance along the optical axis over which the image of the feature is adequately sharp.

The control of the relative size of the illumination system numerical aperture (NA) has historically been used to optimize the resolution of a lithographic projection tool. Control of the NA with respect to the projection systems objective lens NA allows for modification of spatial coherence at the mask plane, commonly referred to as partial coherence (σ). This can be accomplished through the specification of the condenser lens pupil in various illumination systems.

Conventional condenser lens pupils are shown in FIGS. 1A-1C. FIG. 1A shows a conventional circular lens pupil. Other condenser lens pupil arrangements include an annular design, such as that shown in FIG. 1B, and a quadrupole design, such as that shown in FIG. 1C. Conventional systems provide uniform transmission through each of the areas of the lens pupil.

Illumination systems can be further refined by altering the path of illumination. A conventional on-axis illumination system 200 is shown in FIG. 2A. A light source directs light 202 towards and through mask 204. Three diffraction orders, −1, 0, and +1, are transmitted through the lens pupil 206. The three diffraction orders are focused by a lens 208 and are imaged onto a substrate 210. Among other limitations, the on-axis illumination system has a limited depth of focus range, as shown by distance (d₁).

Another illumination system 250, as shown in FIG. 2B, directs light 252 obliquely onto a mask 254 at an angle so that the zero and first diffraction orders are distributed on alternative sides of the optical axis. Such an approach is generally referred to as off-axis illumination (OAI). In the OAI system 250, the two diffraction orders, 0 and +1, are transmitted through the lens pupil 256. The two diffraction orders are focused by a lens 258 and are imaged onto a substrate 260. In OAI, the the mask 254 acts as a diffraction grating for the incident light 252. OAI techniques used with conventional masks can produce resolution enhancement effects similar to resolution enhancement effects obtained with phase shifted masks. Further, OAI system 250 has a somewhat greater depth of focus range than on-axis illumination system 200, as shown by distance (d₂), where (d₂)>(d₁).

Regardless of which illumination system is used, however, optical proximity effects can degrade the integrity of the printed structures. One problem caused by proximity effects using convention systems is an undesirable variation in feature CDs. For any leading edge semiconductor process, achieving tight control over the CDs of the features (i.e., circuit elements and interconnects) is typically the primary manufacturing goal, because that has a direct impact on wafer sort and completion of the final product.

As shown for example in FIG. 3, when forming densely spaced structures, such as contact holes, conventional systems form structures that extend beyond the targeted CD. Extending beyond the targeted CD can form unintended asymmetric structures. FIG. 3 shows a mask design 300 having a plurality of mask features 302 overlain onto a plurality of target features 304 and the resulting printed structures 306. Various rules dictate the position of the mask features 302 on the mask design 300. These rules include the pitch in the x direction, labeled (Pₓ), the pitch in the y direction, labeled (P_{y}), and mask rule violation spacing, which is the closest distance that two mask features can be spaced, labeled (MRV). As shown in FIG. 3, designers intend for each of the mask features 302 to fit inside of the corresponding target features 304. Conventional OAI lithography, however, yields printed structures 306 that are asymmetric, as shown by the portions 306a extending beyond the target features 304. Asymmetry negatively impacts the resulting structures and can lead to errors on a completed device.

Using various lens pupils until now has not been successful in improving contact hole symmetry. For example, FIG. 4A shows the design of a conventional quadrupole lens pupil 400 having four poles 402a-d used in a typical OAI system. Using this combination, however, produces asymmetric contact holes. For example, FIG. 4B shows a plot 450 of the unsatisfactory asymmetry from a conventional OAI system using the quadrupole lens pupil 400. In FIG. 4B, the printed contact holes deviate from the intended circular structures. This can be seen by the contour lines detailing the deviation of CD_{y-x} for various pitches in the x and y direction, where CD_{y-x} is the difference in CD_{y} from CDₓ.

Thus, there is a need to overcome these and other problems of the prior art to produce symmetric structures, such as contact holes, on a substrate.

### SUMMARY OF THE INVENTION

In accordance with an embodiment the invention, there is a device manufacturing method. The method can comprise providing a substrate comprising a radiation-sensitive material disposed thereon and directing a beam of radiation through an aperture such that the radiation produces at least two illumination poles. The method can also comprise exposing the substrate to the at least two illumination poles using off-axis illumination and varying a size of a first illumination pole of the at least two illumination poles with respect to a second illumination pole of the at least two illumination poles.

In accordance with another embodiment the invention, there is a device manufactured by the method comprising providing a substrate comprising a radiation-sensitive material disposed thereon and directing a beam of radiation through an aperture such that the radiation produces at least two illumination poles. The method can also comprise exposing the substrate to the at least two illumination poles using off-axis illumination and varying a size of a first illumination pole of the at least two illumination poles with respect to a second illumination pole of the at least two illumination poles.

In accordance with another embodiment the invention, there is a computer readable medium comprising program code for controlling a lithography system. The computer readable medium can comprise program code for directing a beam of radiation through an aperture such that the radiation produces at least two illumination poles and program code for controlling the exposure of a substrate to the at least two illumination poles using off-axis illumination. The computer readable medium can also comprise program code for varying the size of a first illumination pole of the at least two illumination poles with respect to the size of a second illumination pole of the at least two illumination poles.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1A-1C depict conventional condenser lens pupils.

FIG. 2A depicts an on-axis illumination system.

FIG. 2B depicts an off-axis illumination system.

FIG. 3 depicts the asymmetry of densely spaced structures formed by using conventional systems.

FIG. 4A depicts a conventional quadrupole lens pupil.

FIG. 4B depicts a plot depicting asymmetry in contact holes formed using the conventional quadrupole lens pupil of FIG. 4A.

FIG. 5A depicts an exemplary lens pupil design according to an embodiment of the invention.

FIG. 5B depicts a plot depicting the symmetry in contact holes formed using the lens pupil design of FIG. 5A.

FIG. 6A depicts another exemplary lens pupil design according to an embodiment of the invention.

FIG. 6B depicts a plot depicting the symmetry in contact holes formed using the lens pupil design of FIG. 6A.

FIG. 7A depicts another exemplary lens pupil design according to an embodiment of the invention.

FIG. 7B depicts a plot depicting the symmetry in contact holes formed using the lens pupil design of FIG. 7A.

FIG. 8 depicts the symmetry of densely spaced structures formed according to various embodiments of the invention.

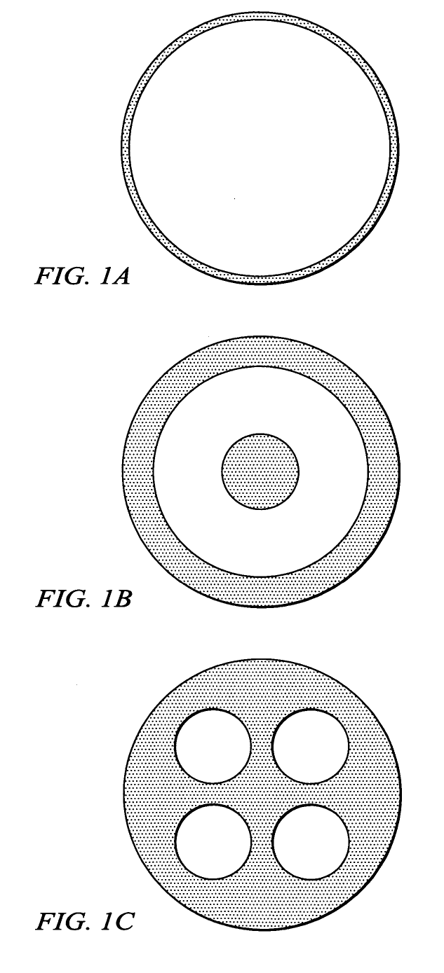

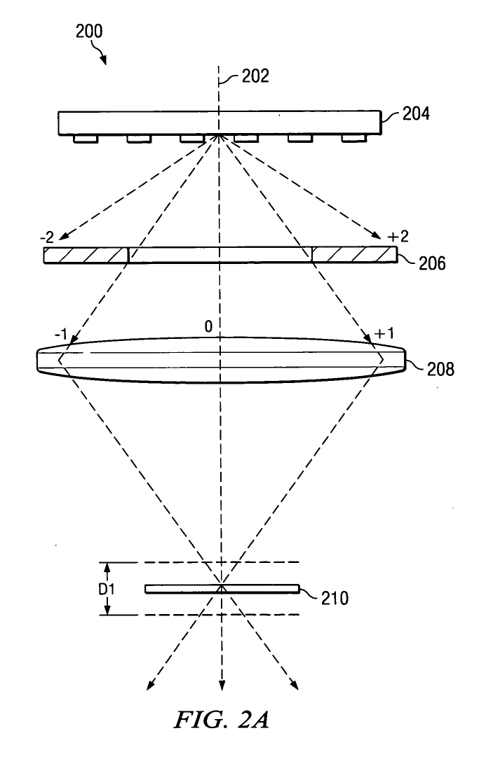

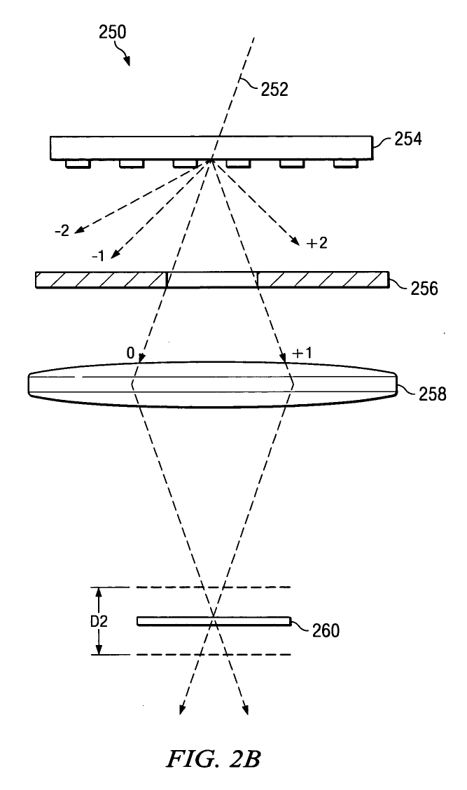

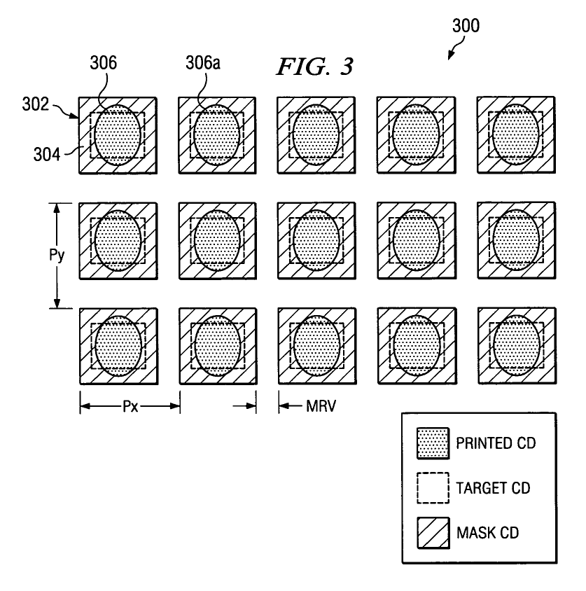

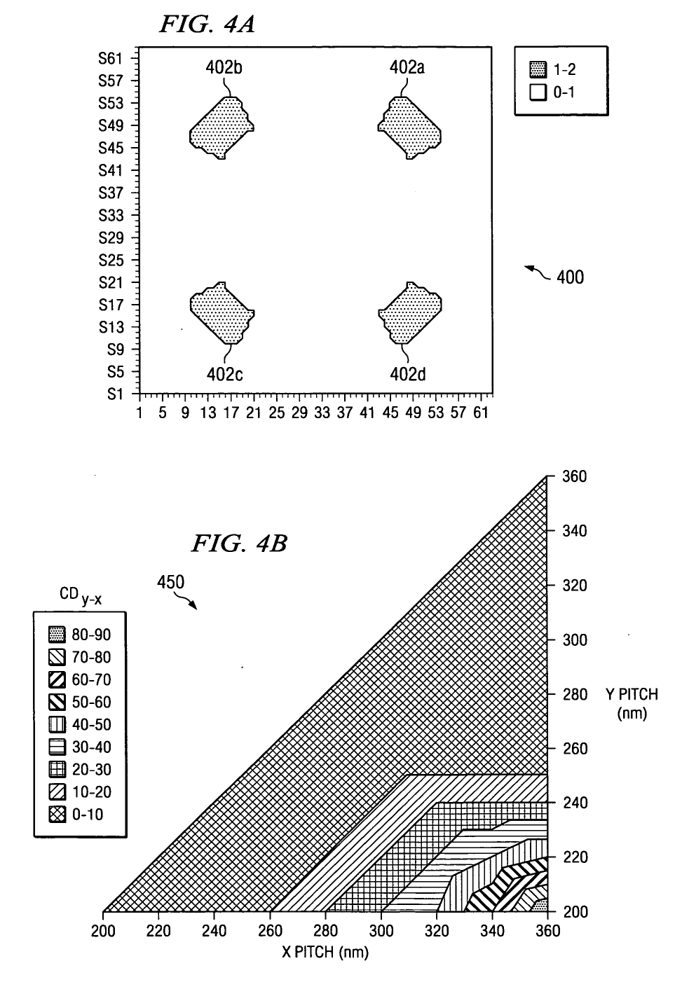

### DESCRIPTION OF THE EMBODIMENTS

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

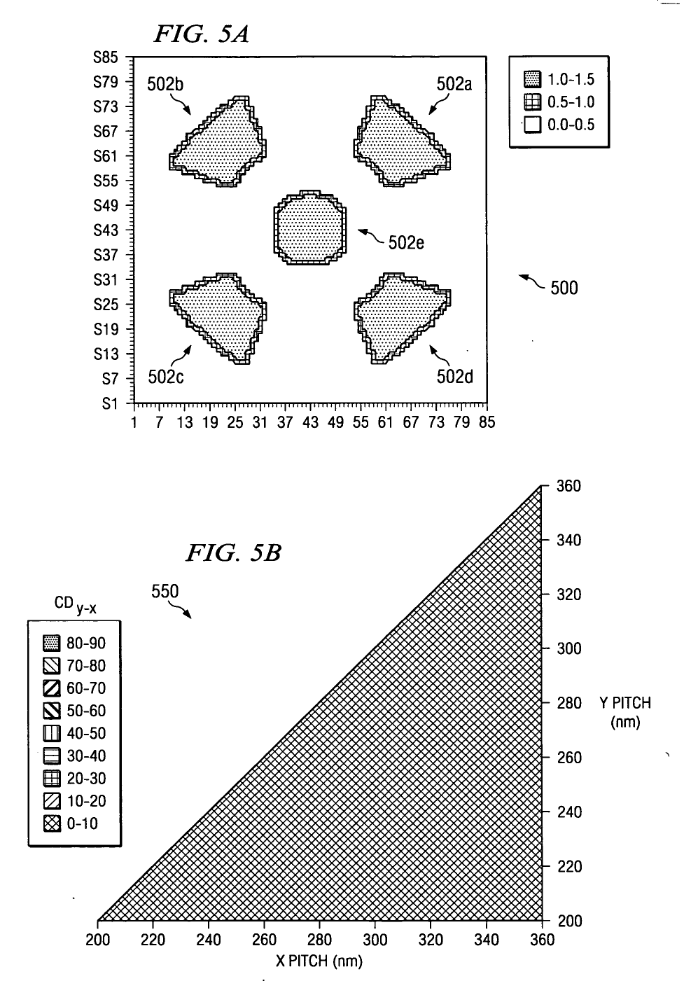

FIGS. 5A-8 depict exemplary methods and devices for use in photolithography for forming symmetric structures on a substrate. According to various embodiments, a beam of radiation, such as light from a light source, can be directed through an aperture, also called a lens pupil in an OAI system. The lens pupil can have more than one illumination pole so as to produce multiple poles of The size, such as the diameter, of at least one of the illumination poles can be varied, with respect to the other poles, so as to control the shape of a printed structure. For example, by varying the size, such as the diameter, of at least one of the illumination poles, symmetric contact holes can be formed. Moreover, when the lens pupil comprises a center pole and an outer pole, varying the relative size, such as the diameter, of the center pole with respect to the size, such as the diameter, of the outer pole can affect optical proximity effects. According to various embodiments, adding and varying the size, such as the diameter, of the center pole can balance out optical proximity effects of the outer poles in a semi-dense pitch region of a resulting device. For example, varying the size, such as the diameter, of the center pole can be used with other optical proximity correction (OPC) techniques to form symmetric contact holes.

FIG. 5A shows an exemplary lens pupil design 500 having five illumination poles 502a-e. Pupil design 500 comprises a plurality of outer poles 502a-d and a center pole 502e. According to various embodiments, the size, such as the diameter, of the center pole 502e can be varied with respect to the size, such as the diameter, of the outer poles 502a-d. For example, the amount of variation can be any amount. In some cases, however, the amount may depend on the variation that can be supported by the lens. Moreover, the amount of variation can depend on, for example, CD bias, target CD, and pitch. In this manner, contact hole asymmetry can be reduced or eliminated. Moreover, varying the size, such as the diameter, of the center pole 502e can improve the overlapping depth of field (DOF) and mask error enhancement factor (MEEF) when forming contact holes.

FIG. 5B shows a plot 550 of the satisfactory symmetry of a structure, such as a contact hole, formed on a substrate when the center pole size, such as the diameter, of lens pupil design 500 is varied. According to various embodiments, the dimensions of the printed contact holes accurately fit into the targeted design for all pitch combinations. For each pitch combination, CD_{y-x} is less than 10 nm. Further, the aspect ratio of the structures are from about 1.0 to about 1.5.

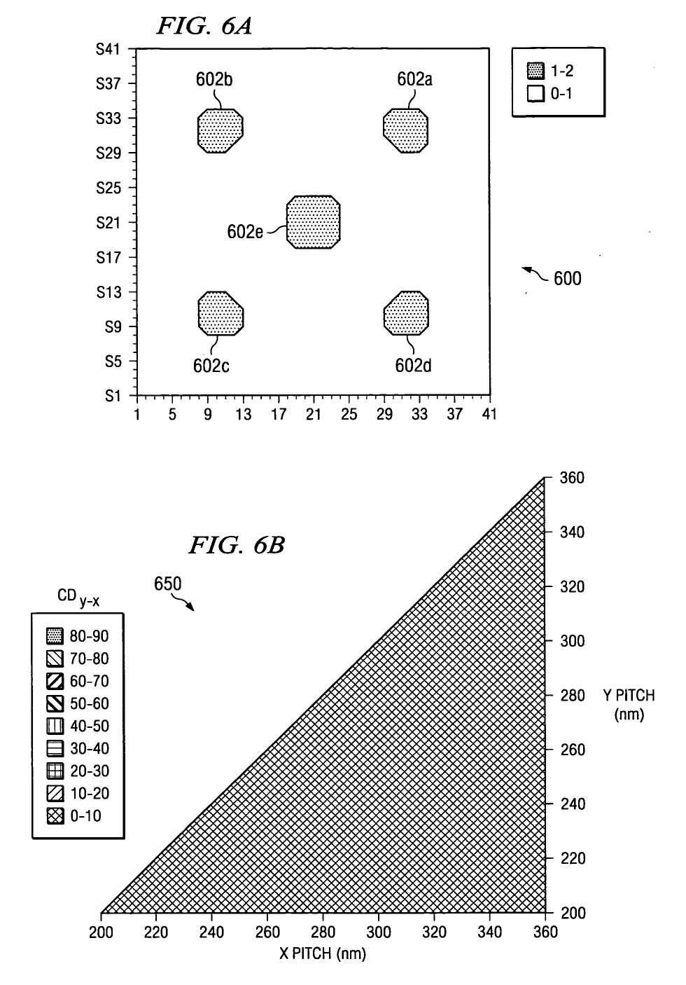

Another exemplary lens pupil design 600 having five illumination poles 602a-e is shown in FIG. 6A. Varying the relative center pole 602e size, such as the diameter, with respect to the size, such as the diameter, of the outer poles 602a-d can affect OPC effects. Again, the addition of a center pole and the variation in the size, such as diameter, of the center pole, acts to balance out the proximity effects that the outer poles can have on semi-dense pitch regions of the resulting device thereby making contact holes in question correctable using OPC. Still further, varying the relative center pole 602e size, such as the diameter, can improve the overlapping depth of field (DOF) and mask error enhancement factor (MEEF) when forming contact holes.

FIG. 6B shows a plot 650 of the satisfactory symmetry of a structure, such as a contact hole, formed on a substrate when the size, such as the diameter, of the center pole of the lens pupil design 600 is varied. According to various embodiments, the dimensions of the printed contact holes accurately fit into the targeted design for all pitch combinations. For each pitch combination, CD_{y-x} is less than 10 nm. Further, the aspect ratios of the structures are from about 1.0 to about 1.5.

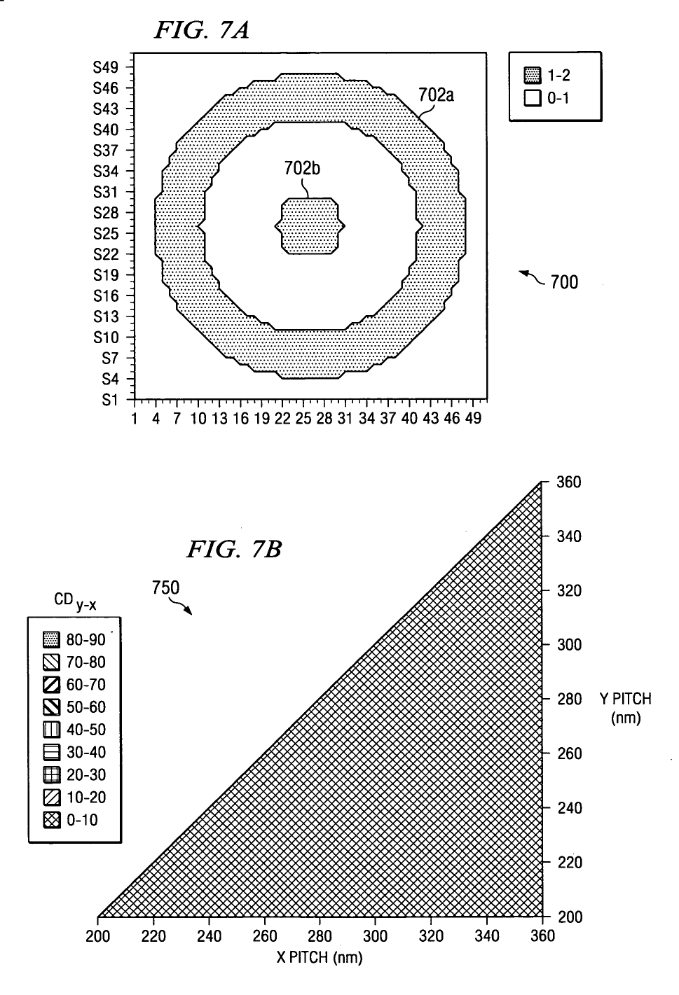

Another exemplary lens pupil design 700 having two illumination poles 702a and 702b is shown in FIG. 7A. Varying the relative center pole 702b size, such as the diameter, with respect to the size, such as the diameter, of the outer pole 702a can affect OPC effects. Still further, varying the relative size, such as the diameter, of the center pole 702b can improve the overlapping depth of field (DOF) and mask error enhancement factor (MEEF) when forming contact holes.

FIG. 7B shows a plot 750 of the satisfactory symmetry of a structure, such as a contact hole formed on a substrate, when the size, such as the diameter, of center pole 702b of the lens pupil design 700 is varied. According to various embodiments, the dimensions of the printed contact holes accurately fit into the targeted design for all pitch combinations. For each pitch combination, CD_{y-x} is less than 10 nm. Further, the aspect ratios of the structures are from about 1.0 to about 1.5.

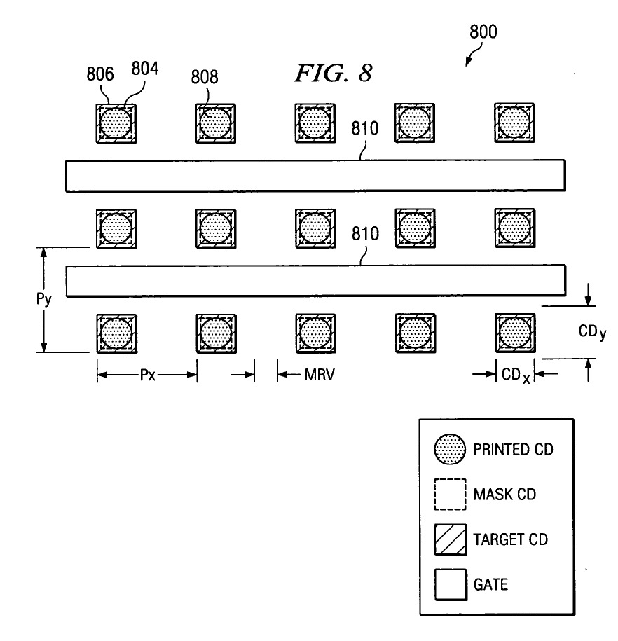

FIG. 8 depicts a portion of a mask design 800 having mask features 804 overlain onto a portion of a layout having target features 806 and the resulting printed structures 808. The printed structures 808 are examples of structures, such as contact holes, formed by varying the size, such as the diameter of the center pole of the lens pupil, such as those disclosed herein. FIG. 8 also depicts gate structures 810 formed on the substrate. Some of the rules that dictate the position of the mask features 804 on the mask design 800 are also shown in FIG. 8. These rules include the pitch in the x direction, labeled (Pₓ), the pitch in the y direction, labeled (P_{y}), and mask rule violation spacing, which is the closest distance that two mask features can be spaced, labeled (MRV). According to various embodiments, (Pₓ) need not be the same as (P_{y}), although in some cases the two pitches may be equal.

As shown in FIG. 8, the designer intends for each of the mask features 804 to produce structures that match the corresponding target features 806. In FIG. 8, the printed structures 808 fit within the target features, indicating that the designer's intentions have been met. For example, the printed structures 808 are more symmetric. Moreover, the corresponding aspect ratio of the printed structures can be from about 1.0 to about 1.5.

According to various embodiments, a computer readable medium can be provided that configures a processor to control a lithography system, such as those described herein. The computer readable medium can include program code for directing a beam of radiation through an aperture such that the radiation produces at least two illumination poles and program code for controlling the exposure of a substrate to the at least two illumination poles using off-axis illumination. The computer readable medium can further include program code for varying the size, such as the diameter, a first illumination pole of the at least two illumination poles with respect to the size, such as the diameter, a second illumination pole of the at least two illumination poles.

According to various embodiments, the computer readable medium can include program code for directing a beam of radiation through an aperture such that the radiation produces at least two illumination poles. The computer readable medium can also include program code for controlling the exposure of a substrate to the at least two illumination poles using off-axis illumination and program code for varying the size of a first illumination pole of the at least two illumination poles with respect to the size of a second illumination pole of the at least two illumination poles.

According to various embodiments, the aperture controlled by the computer readable medium can produces a center illumination pole surrounded by four other illumination poles. Further, the center illumination pole can correspond to the first illumination pole. Moreover, the size of the first illumination pole can be varied by varying the diameter of the first illumination pole. Still further, the size of the first illumination pole can be varied such that the features on the substrate comprise an aspect ratio from 1.0 to 1.5.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A device manufacturing method comprising:
providing a substrate comprising a radiation-sensitive material disposed thereon;
directing a beam of radiation through an aperture such that the radiation produces at least two illumination poles;
exposing the substrate to the at least two illumination poles using off-axis illumination; and
varying a size of a first illumination pole of the at least two illumination poles with respect to a second illumination pole of the at least two illumination poles.

2. The device manufacturing method according to claim 1 further comprising:
controlling an aspect ratio of a feature formed on the substrate by varying the size of the first illumination pole.

3. The device manufacturing method according to claim 1, wherein directing the radiation through an aperture produces five illumination poles, wherein four illumination poles are arranged symmetrically around a fifth center illumination pole.

4. The device manufacturing method according to claim 2, wherein the size of the first illumination pole is varied by varying the diameter of the first illumination pole.

5. The device manufacturing method according to claim 3, wherein the size of the first illumination pole is varied by varying the diameter of the first illumination pole.

6. The device manufacturing method according to claim 1, wherein the aperture comprises a concentric circle pattern.

7. The device manufacturing method according to claim 5, wherein the diameter of the center illumination pole is reduced with respect to the diameter of the four illumination poles around the center illumination pole.

8. The device manufacturing method according to claim 2, wherein the feature comprises a first critical dimension (CDₓ) and a second critical dimension (CD_{y}), and wherein,
(CD_{y})−(CDₓ)<10 nm.

9. The device manufacturing method according to claim 1, wherein the amount of first illumination pole variation depends on CD bias, target CD size, and pitch.

10. The device manufacturing method according to claim 5, wherein the amount of center illumination pole variation depends on CD bias, target CD size, and pitch.

11. A device manufactured by the method comprising:
providing a substrate comprising a radiation-sensitive material disposed thereon;
directing a beam of radiation through an aperture such that the radiation produces at least two illumination poles;
exposing the substrate to the at least two illumination poles using off-axis illumination; and
varying a size of a first illumination pole of the at least two illumination poles with respect to a second illumination pole of the at least two illumination poles.

12. The device manufactured by the method according to claim 11, wherein the size of the first illumination pole varied such that the features on the substrate comprise an aspect ratio from 1.0 to 1.5.

13. The device manufactured by the method according to claim 11, wherein the beam of radiation passes through an aperture such that the radiation produces a center illumination pole surrounded by four other illumination poles.

14. The device manufactured by the method according to claim 13, wherein the size of the center illumination pole is reduced with respect to the size of each of the four other illumination poles.

15. The device manufactured by the method according to claim 11, wherein (Pₓ)≠(P_{y}).

16. A computer readable medium comprising program code for controlling a lithography system, the computer readable medium comprising:
program code for directing a beam of radiation through an aperture such that the radiation produces at least two illumination poles;
program code for controlling the exposure of a substrate to the at least two illumination poles using off-axis illumination; and
program code for varying the size of a first illumination pole of the at least two illumination poles with respect to the size of a second illumination pole of the at least two illumination poles.

17. The computer readable medium comprising program code for controlling a lithography system according to claim 16, wherein the aperture produces a center illumination pole surrounded by four other illumination poles.

18. The computer readable medium comprising program code for controlling a lithography system according to claim 16, wherein the center illumination pole corresponds to the first illumination pole.

19. The computer readable medium comprising program code for controlling a lithography system according to claim 16, wherein the size of the first illumination pole is varied by varying the diameter of the first illumination pole.

20. The computer readable medium comprising program code for controlling a lithography system according to claim 19, wherein the size of the first illumination pole is varied such that the features on the substrate comprise an aspect ratio from 1.0 to 1.5.
